(19) United States
(12) Patent Application Publication
(10) Pub. No.: US 2024/0302304 A1
(43) Pub. Date: Sep. 12, 2024

(54) ELECTRON MICROSCOPE FOR EXAMINING A SPECIMEN

(71) Applicant: Carl Zeiss SMT GmbH, Oberkochen (DE)

(72) Inventors: Moritz Becker, Aalen (DE); Eugen Foca, Ellwangen (DE)

(21) Appl. No.: 18/661,793

(22) Filed: May 13, 2024

Related U.S. Application Data
(63) Continuation of application No. PCT/EP2022/085609, filed on Dec. 13, 2022.

(30) Foreign Application Priority Data
Dec. 15, 2021 (DE) 102021214447.0

(51) Int. Cl. G01N 23/2202; G01N 23/2251; H01J 37/28

(52) U.S. Cl. CPC G01N 23/2202; G01N 23/2251; H01J 37/28; G01N 2223/6116

(57) ABSTRACT

An electron microscope serves for examining a specimen. An electron optical unit serves for passing an image of a specimen region of interest to a detection device. A removal device serves for removing material from the specimen, in the specimen region of interest, in preparation for imaging of the specimen region. A stop serves for separating the specimen region of interest from a specimen environment. The result is an electron microscope in which undesired effects of the removal device on the specimen to be examined are reduced.

### CROSS-REFERENCE TO RELATED APPLICATIONS

This application is a continuation of and claims priority under 35 U.S.C. § 120 from PCT application PCT/EP2022/085609, filed on Dec. 13, 2022, which claims priority from German patent application DE 10 2021 214 447.0, filed on Dec. 15, 2021. The entire contents of each of these priority applications are incorporated herein by reference.

### TECHNICAL FIELD

The invention relates to an electron microscope for examining a specimen.

### BACKGROUND

An electron microscope that can be used for examining a specimen, in particular for examining a lithography mask for EUV projection lithography, is known from U.S. Pat. No. 8,969,835 B2. DE 102 08 043 A1 discloses a material processing system, its use and a gas supply to be used in the material processing system. US 2007/0187622 A1 discloses a charged particle beam apparatus, a defect correcting method, and etching method, a deposition method and a charge preventing method.

An electron microscope of this kind can be designed as a crossbeam examination system in which, during a measuring process, the specimen can be removed layer by layer via a removal device. The removal device can be a focused ion beam device.

### SUMMARY

It is an aspect of the present invention to develop an electron microscope of the type mentioned at the outset, in such a way as to avoid a removal device having undesired effects on the specimen that is to be examined.

This aspect is achieved, according to the invention, by an electron microscope having the features set forth in Claim 1.

According to the invention, it has been found that specimen material, which is generated during removal by the removal device, for example by focused ion beams, in particular by sputtering, and/or removal material used itself in the removal process, is prevented, by the stop, from depositing itself on the specimen environment. The removal material can be sputtering material. Beyond the specimen region of interest, the specimen is not then undesirably damaged during the examination by the electron microscope. If, for example, a wafer with semiconductor chip structures is examined, it is then possible to ensure that, during the electron microscopy examination, precisely just one chip structure lies in the specimen region of interest, and therefore all the other chip structures are protected by the stop.

A stop arrangement according to Claim 2 permits efficient protection of the specimen environment from contamination, which can be caused by the removal device and/or the electron optical unit.

A stop window according to Claim 3 ensures that the stop does not undesirably disturb the measuring operation.

Contact portions according to Claim 4 ensure a reliable division between the specimen region of interest and the specimen environment. In particular, the entire window edge contour can be in contact, via edge regions of the stop, with the specimen outside of the specimen region of interest.

Cutting edges according to Claim 5 ensure a particularly reliable separation between the specimen region of interest and the specimen environment. Such cutting edges can be made from metal or from ceramic. An indentation depth of the respective cutting edge in the material of the specimen can be less than 100 nm, less than 50 nm and less than 20 nm. When using at least one cutting edge, the indentation depth is regularly greater than 0.

Sealing edges as edge regions according to Claim 6 permit non-destructive contact of the stop with the specimen. The sealing edges can be produced from elastomeric sealing material, for example from FKM or FFKM or silicone. Alternatively, the sealing edges can be produced from thermoplastic sealing material, for example from POM or from PEEK. The material of the sealing edges can have a low Shore hardness. The Shore hardness of the material of the sealing edges is preferably less than 75 Shore A and particularly preferably less than 40 Shore A.

The sealing edges can have a spring body which ensures an elastic connection between a touching region of the sealing edge and the rest of the contact portion.

A flexural hinge according to Claim 7 likewise permits an elastic bearing between an edge region of the stop and the specimen.

A proximity region of the stop according to Claim 8 ensures non-destructive interaction between stop and specimen. The minimum distance can be at most 100 μm, at most 50 μm, at most 20 μm, at most 10 μm or also at most 1 μm. The minimum distance is regularly more than 0.2 μm.

A distance adaptation according to Claim 9 avoids undesired damage to valuable specimen structures. In the examination of chip structures on a wafer, it is possible to ensure that only the respective chip being examined constitutes the specimen region of interest, whereas all the other chip structures on the specimen lie in the specimen environment protected by the stop and also cannot be damaged by the edge regions of the stop.

A sealing effect of the contact portions results in a particularly safe separation of the measuring space from the environment space. A corresponding sealing effect can also be achieved via a proximity region situated correspondingly close to the specimen surface.

Particularly if a sealing effect according to Claim 10 is present, a gas source according to Claim 11 can be used to flush the specimen environment and/or the specimen region of interest, in particular for targeted discharge of removed specimen material and/or sputter material. It is thus ensured that such material does not undesirably pass into the environment space.

A displaceability of the stop relative to the specimen, according to Claim 12, permits a defined positioning of the stop with respect to the specimen, and in particular a defined sealing via the contact portions and/or a defined approximation via the proximity regions.

Displaceable stop portions according to Claim 13 can be designed as stop slides, which are slidable relative to a main body of the stop. Stop slides of this kind can be sealed off in relation to the main body of the stop, which can be effected in turn via a labyrinth seal, for example.

A set according to Claim 14 and/or according to Claim 15 permits the choice of a stop having in each case a stop window size and/or stop window position adapted to the necessary size and/or position of the specimen region of interest. The individual stops of the set can each be selected via an interchange holder, which withdraws the selected stop from a stop magazine and if appropriate exchanges it for another selected stop.

### BRIEF DESCRIPTION OF DRAWINGS

Exemplary embodiments of the invention are explained in more detail below with reference to the drawings. In these drawings:

FIG. 1 shows a schematic side view of an electron microscope for crossbeam examination of a specimen;

FIG. 2 shows a side view and a cross section of a sputter gun of the electron microscope together with the specimen to be examined and a stop for separating a specimen region of interest from a specimen environment during sputtering of a wedge-shaped specimen crater;

FIG. 3 shows an enlarged view of the detail III in FIG. 2;

FIG. 4 shows, in a view similar to FIG. 3, a variant of an edge region of a contact portion of a window edge contour of a stop window of the stop; and

FIG. 5 shows schematically, but in greater detail compared to FIGS. 1 to 4, an example of the specimen to be examined, designed as a wafer with a total of three adjacent chip structures shown in cross section, with an embodiment of the stop of the electron microscope having edge regions of the contact portions corresponding to the window edge contour of the stop window according to FIG. 3.

### DETAILED DESCRIPTION

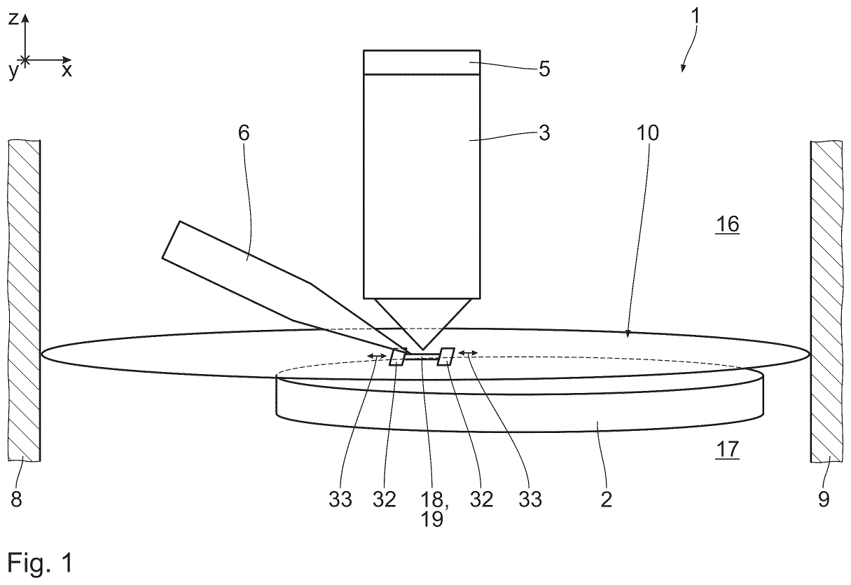

FIG. 1 shows an embodiment of an electron microscope 1, which can be designed as a scanning electron microscope (SEM). The electron microscope 1 serves for examining a specimen 2, which can be a semiconductor wafer.

Orientations and dimensions are described below using a Cartesian coordinate system. In FIG. 1, the x-axis runs to the right. The y-axis runs perpendicular to the drawing plane and into the latter. In FIG. 1, the z-axis runs upwards.

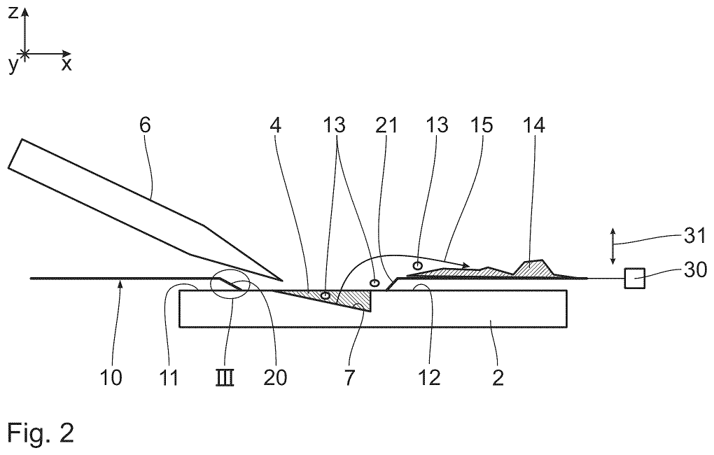

The electron microscope 1 has an electron optical unit 3 for passing an image of a specimen region 4 of interest (cf. FIG. 2) to a detection device 5.

A removal device 6, which is designed as a sputter gun, serves for removing material from the specimen 2 in the specimen region 4 of interest, in preparation for imaging of the specimen region by the electron optical unit 3. FIG. 2 shows an instantaneous situation during the operation of the sputter gun 6. A wedge-shaped crater 7 is removed layer by layer in the specimen 2. After each removal of a layer, a specific scanning measurement is performed with the electron optical unit 3.

The specimen 2 is accommodated in a measuring chamber, which is delimited by lateral chamber walls 8, 9.

A stop 10 serves for separating the specimen region 4 of interest from a specimen environment 11, 12 of a specimen surface around the specimen region 4 of interest. In contrast to what is shown in FIG. 1, the stop 10 can be configured in particular as a housing of the specimen body, e.g. wafer, i.e. the specimen environment 11, 12, without direct contact with the chamber walls.

As can be seen from the sputtering process illustrated schematically in FIG. 2, material 14 of the specimen is removed as removal material from the crater 7, through atomization by sputter ions 13, is transferred to the surface of the stop 10 and deposits itself there. The effect of the stop 10 is therefore that the material 14 removed from the specimen region 4 of interest by use of the removal device 6 is not deposited on the specimen environment 11, 12. This removal and subsequent deposition is illustrated in FIG. 2 by a removal arrow 15.

The stop 10 (cf. FIG. 1) is arranged between the chamber walls 8, 9 in such a way that a measuring space above the specimen 2 is divided into a processing space 16, in which the electron optical unit 3 and the sputter gun 6 are located, and a specimen space 17, in which the specimen 2 is located.

The stop 10 has a stop window 18 via which the specimen region 4 of interest is accessible to the sputter gun 6 and to the electron optical unit 3.

The stop window 18 has a window edge contour 19, which is rectangular in the embodiment shown.

The window edge contour 19 is in contact, via contact portions in the form of edge regions 20, 21 of the stop 10, with the specimen 2 outside of the specimen region 4 of interest. This is illustrated in FIGS. 2 to 5 using the example of edge regions 20, 21 of the stop 10 that run along the y-direction perpendicular to the drawing plane of FIGS. 2 to 5. In addition, the stop window 18 can moreover be delimited by at least two further edge regions of the window edge contour 19, which further edge regions run along the x-direction in front of and behind the drawing plane of FIGS. 2 to 5 and at a distance from said plane.

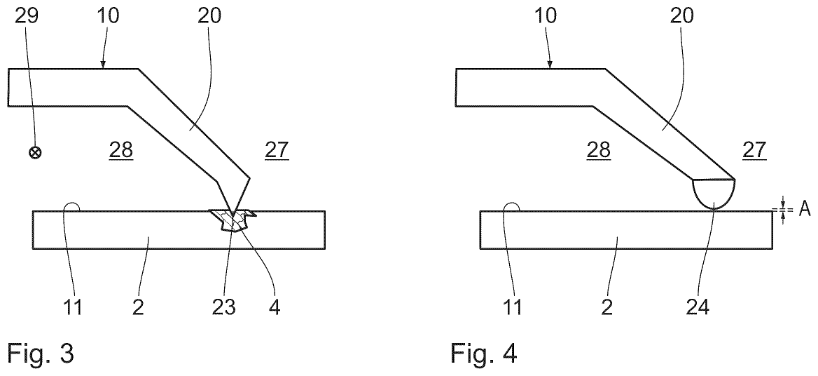

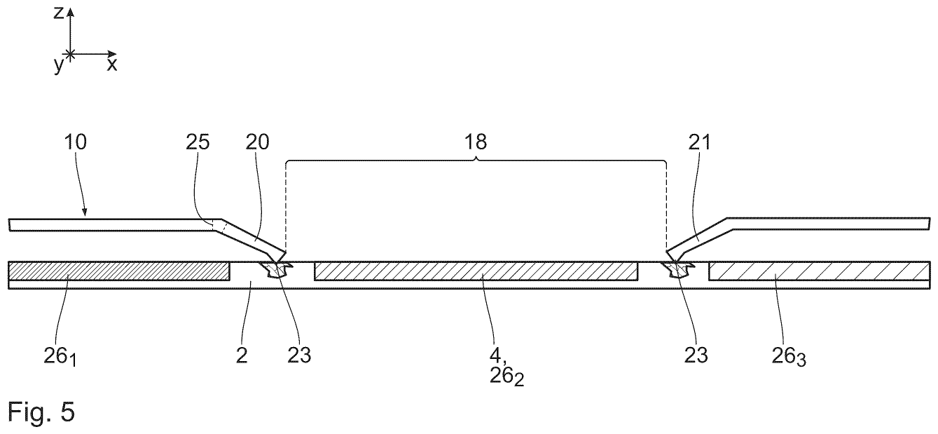

FIGS. 3 and 5 show an embodiment in which the edge regions have cutting edges 23, which work their way into the material of the specimen 2 upon contact.

FIG. 4 shows a further embodiment in which the edge regions have sealing edges 24 that touch non-destructively. Material variants for the sealing edges 24 can be an elastomeric sealing material, for example FKM (fluoro rubber) or FFKM (perfluoro rubber) or silicone, or a thermoplastic sealing material, for example POM (polyoxymethylene) or PEEK (polyether ether ketone). Other elastic or plastic sealing materials are also possible. The respective sealing edge 24 is firmly connected to the main body of the stop and/or the contact portions 20, 21. Alternatively, the whole of the edge regions 20, 21 or also the whole stop 10 can be produced from the material of the sealing edges 24.

The cutting edges 23 can be integrally moulded onto the material of the edge regions 20, 21. Alternatively, the cutting edges 23 can also be made of a material different from that of the rest of the edge regions 20, 21 or the rest of the stop 10.

The cutting edges 23 can be produced from metal or ceramic or diamond.

The edge regions 20, 21 can have a flexural hinge 25, shown by a broken line in FIG. 5, in order to achieve a sufficiently slight indentation, so that destruction of the specimen (e.g., wafer cleaving) or of the adjacent structures (e.g., by subsurface crack propagation) is avoided. The admissible indentation depth depends on the design of the cutting edge 23 and is typically <50 nm, preferably <20 nm. The cutting edges can be oriented parallel to primary crystal orientation planes of the specimen or deliberately at an acute angle of 0.1° to 10°, preferably 0.1° to 5°.

FIG. 5 shows a dimensioning of the stop window 18, which is adapted to the extent of a chip structure 26 on the specimen 2 to be examined. An x-distance between the edge regions 20, 21 is adapted to a repetition period of the chip structures 26₁, 26₂, 26₃. In the instantaneous situation according to FIG. 5, the middle chip structure 26₂ is examined, which is at the same time the specimen region 4 of interest.

The contact portions 20, 21 can seal off a measuring space 27, comprising the specimen region 4 of interest, from an environment space 28 which comprises the specimen environment 11, 12 outside of the specimen region 4 of interest. By way of a gas source 29, indicated schematically in FIG. 3, the environment space 28 can be kept at a pressure higher than a pressure in the measuring space 27. Such an overpressure can also be achieved by pumping out the measuring space 27.

The stop 10 can be operatively connected to a stop drive 30, via which the stop 10 is movable relative to the specimen 2, in particular along the z-direction, as is illustrated in FIG. 2 by a double arrow 31.

The stop 10 can have a plurality of stop portions 32 which are displaceable in order to predefine a stop window size and which can be configured in the manner of stop slides that are designed to be displaceable relative to a main body of the stop along the x-direction (double arrow 33) and/or along the y-direction. Alternatively or in addition, the electron microscope 1 can be equipped with a set of stops, in accordance with the stop 10, which have stop windows 18 of different sizes. By use of these stop windows of different sizes, it is possible to adapt the respective stop 10 to the size of the region 4 of interest, and in particular to adapt it to a chip structure spacing (period according to FIG. 5).

In an embodiment of the stop 10 merely indicated in FIG. 4, proximity regions of a window edge contour of the stop 10 are designed such that a minimum distance (A) (cf. FIG. 4) remains between the proximity regions, which correspond to the sealing edges 24 of the embodiment according to FIG. 4, and a specimen surface, so that the stop 10 does not touch the specimen 2. An upper limit for the minimum distance A can be 10 μm. This upper limit can be less, for example 8 μm, 5 μm, 3 μm or 1 μm. This upper limit is regularly more than 0.5 μm.

What is claimed is:

1. An electron microscope for examining a specimen, the electron microscope comprising:
an electron optical unit for passing an image of a specimen region of interest to a detection device,
a removal device for removing material from the specimen, in the specimen region of interest, in preparation for imaging of the specimen region,
a stop for separating the specimen region of interest from a specimen environment,
wherein the stop is designed such that specimen material, which is generated during removal by the removal device and/or removal material used itself in the removal process, is prevented by the stop from depositing itself on the specimen environment.

2. The electron microscope of claim 1, wherein the stop is arranged in such a way that a measuring space above the specimen to be examined is divided into a processing space, in which the electron optical unit and the removal device are located, and a specimen space, in which the specimen is located.

3. The electron microscope of claim 1, wherein the stop has a stop window via which the specimen region of interest is accessible to the removal device and the electron optical unit.

4. The electron microscope of claim 3, wherein at least contact portions of a window edge contour of the stop window are in contact, via edge regions of the stop, with the specimen outside of the specimen region of interest.

5. The electron microscope of claim 4, wherein the edge regions of the contact portions are designed as cutting edges which are in contact with the specimen during the measuring operation of the electron microscope.

6. The electron microscope of claim 4, wherein the edge regions of the contact portions are designed as sealing edges which touch the specimen non-destructively during the measuring operation.

7. The electron microscope of claim 4, wherein the edge regions have a flexural hinge.

8. The electron microscope of claim 1, wherein proximity regions of a window edge contour of the stop window of the stop are designed such that a minimum distance remains between the proximity regions and a specimen surface of the specimen during the measuring operation, so that the stop does not touch the specimen.

9. The electron microscope of claim 4, wherein distances between the contact portions or between the proximity regions are adapted to a repetition period of structures on the specimen that is to be examined.

10. The electron microscope of claim 4, wherein the contact portions or the proximity regions seal off a measurement space, comprising the specimen region of interest, from an environment space which comprises a specimen environment outside of the specimen region of interest.

11. The electron microscope of claim 10, comprising a gas source via which the environment space is kept at a pressure higher than a pressure in the measurement space.

12. The electron microscope of claim 1, wherein the stop is displaceable relative to the specimen.

13. The electron microscope of claim 1, wherein the stop has a plurality of stop portions which are displaceable for predefining a stop window size.

14. The electron microscope of claim 1, comprising a set of stops having different sizes of stop windows.

15. The electron microscope of claim 1, comprising a set of stops having a different basic position of the stop window relative to the specimen.

16. The electron microscope of claim 2, wherein the stop has a stop window via which the specimen region of interest is accessible to the removal device and the electron optical unit.

17. The electron microscope of claim 2, wherein proximity regions of a window edge contour of the stop window of the stop are designed such that a minimum distance remains between the proximity regions and a specimen surface of the specimen during the measuring operation, so that the stop does not touch the specimen.

18. The electron microscope of claim 2, wherein the stop is displaceable relative to the specimen.

19. The electron microscope of claim 2, wherein the stop has a plurality of stop portions which are displaceable for predefining a stop window size.

20. The electron microscope of claim 2, comprising a set of stops having different sizes of stop windows.
